(19) United States
(12) Patent Application Publication
(10) Pub. No.: US 2010/0109156 A1
(43) Pub. Date: May 6, 2010

(54) BACK SIDE PROTECTIVE STRUCTURE FOR A SEMICONDUCTOR PACKAGE

(75) Inventors: Yu-Shan Hu, Yangmei Township (TW); Shih-Chuan Wei, Yuanlin Township (TW); Dyi-Chung Hu, Chutung Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 12/264,513

(22) Filed: Nov. 4, 2008

(51) Int. Cl. H01L 23/488; H01L 21/304

(52) U.S. Cl. 257/737; 438/113; 257/E23.023; 257/E21.238

(57) ABSTRACT

The present invention provides a semiconductor device package, comprising a die having a back surface and an active surface formed thereon; a conductive layer formed upon the back surface of the die; and a protection substrate formed on the conductive layer. An adhesive layer is formed between the conductive layer and the protective layer, if necessary. The present invention further provides a method for forming a semiconductor device package, comprising providing a plurality of die having a back surface and an active surface on a wafer; forming a conductive layer upon the back surface of the die; forming protection substrates on the conductive layer; forming a plurality of bumps on the active surface of each die; and dicing the plurality of die into individual die for singulation by exerting external force on the substrate. An adhesive layer is formed between the conductive layer and the protective layer, if necessary.

### FIELD OF THE INVENTION

This invention relates to a structure of semiconductor device package, and more particularly to a structure of semiconductor device package having a back side protective scheme, thereby protecting the package body and improving the reliability.

### BACKGROUND OF THE INVENTION

### Description of the Prior Art

In recent years, the high-technology electronics manufacturing industries have launched more feature-packed and humanized electronic products. Rapid development of semiconductor technology has led to rapid progress of a reduction in size of semiconductor packages, the adoption of multi-pin, the adoption of fine pitch, the minimization of electronic components and the like.

Conventional package technologies have to divide a dice on a wafer into respective dice and then package the die respectively, and therefore these techniques are time consuming for the manufacturing process. The chip package technique is highly influenced by the development of integrated circuits, therefore, as the size of electronics has become demanding, so does the package technique. For the reasons mentioned above, the trend of package technique today is toward ball grid array (BGA), flip chip ball grid array (FC-BGA), chip scale package (CSP), and Wafer level package (WLP). “Wafer level package” is to be understood as meaning that the entire packaging and all the interconnections on the wafer, as well as other processing steps, are carried out before the singulation (dicing) into chips (dice). By wafer level packaging technology, we can produce die with extremely small dimensions and good electrical properties. Though the advantages of WLP technique mentioned above, some issues still exist influencing the acceptance of WLP technique. Traditionally, due to the package structure having multiple-chips, the sizes of the package structure increases with the numbers or total heights of multiple dice, so that the processes are more complex.

FIG. 1 illustrates the cross-section diagram of the conventional package with bottom surface protective coating disclosed by U.S. Pat. Nos. 6,023,094 and 6,175,162. The package structure 200 comprises a die 102 having a bottom surface 104 and a top surface 108. The package structure 200 further comprises a protective film 210 formed on the bottom surface 104 of the die 102 to cover the bottom surface 104, and a plurality of bumps 106 formed on the top surface 104 of the die 102. Further, the size of the protective film 210 is the same as the size of the chip 102. The protective film 210 has low thermal conductivity around 0.2, and the thickness is approximately 1.5-5 mils. Accordingly, the size of the package structure 200 is accumulated and equivalent to the total sizes of each material layer, and the differences of the thermal conductivity among each material layer are remarkable for poor adhesion among the material layers.

Further, the material of the protective film 210 usually includes epoxy or rubber materials. When epoxy material is employed for the protective film 210, in order to offer proper protection, the epoxy must be thicker than others due to the material property. However, the protective film 210 will be too thick to warp during the manufacture process and it is very easily cracked during dicing saw or by outside force. If rubber material is employed for the protective film 210, the hardness of the protective film 210 is usually insufficient to protect the package structure. However, the processes for manufacturing the package structure also become more and more complex and costly. In conclusion, the thickness or hardness of the protective film 210 is a serious concern and it is insufficient to protect the package structure at present.

If we utilizes a soft substrate, the adhesive commonly used cannot bind the substrate tight enough and therefore the soft substrate might be stripped; another question is that the soft substrate cannot provide EMI shielding or cannot provide EMI shielding as good as the metal substrate does.

In view of the aforementioned, a structure is required to overcome the above drawbacks.

### SUMMARY OF THE INVENTION

One advantage of the present invention is providing a protective structure for EMI shielding.

Another advantage of the present invention is providing a protective structure for avoiding edge chipping.

Still another advantage of the present invention is providing a protective structure with a conductive layer between a substrate and an adhesive layer for having the substrate more stably fixed on the package.

Still another objective of the present invention is providing a structure of semiconductor device package having a back side protective scheme, which can lower costs and improve the reliability.

Still another objective of the present invention is providing a structure of semiconductor device package having a back side protective structure, which can easily perform the laser marking on the top surface of the semiconductor device package.

Another objective of the present invention is to provide a structure of semiconductor device package having a back side protective scheme, which solves the crack and warp issues during process.

The present invention provides a structure of semiconductor device package, comprising a die having a back surface and an active surface formed thereon; a conductive layer formed upon said back surface of said die wherein said conductive layer is elastic and contains conductive material; a protection substrate formed on said conductive layer; and a plurality of bumps formed on said active surface of said die. An adhesive layer is added between the conductive layer and the protective substrate, if necessary.

The present invention provides a method for forming a semiconductor device package, comprising providing a plurality of die having a back surface and an active surface on a wafer; forming a conductive layer upon the back surface of the die; forming a protection substrates on the conductive layer; forming a plurality of bumps on the active surface of each die; and dicing the plurality of die into individual die for singulation by exerting external force in the substrate. An adhesive layer is formed between the conductive layer and the protective layer, if necessary.

### BRIEF DESCRIPTION OF THE DRAWINGS

The foregoing aspects and many of the attendant advantages of this invention will become more readily appreciated as the same becomes better understood by reference to the following detailed description, taken in conjunction with the accompanying drawings, wherein:

FIG. 1 illustrates a cross-section diagram of a structure of semiconductor device package according to the prior art; and

FIG. 2 illustrates a cross-section diagram of a structure of semiconductor device package according to the present invention.

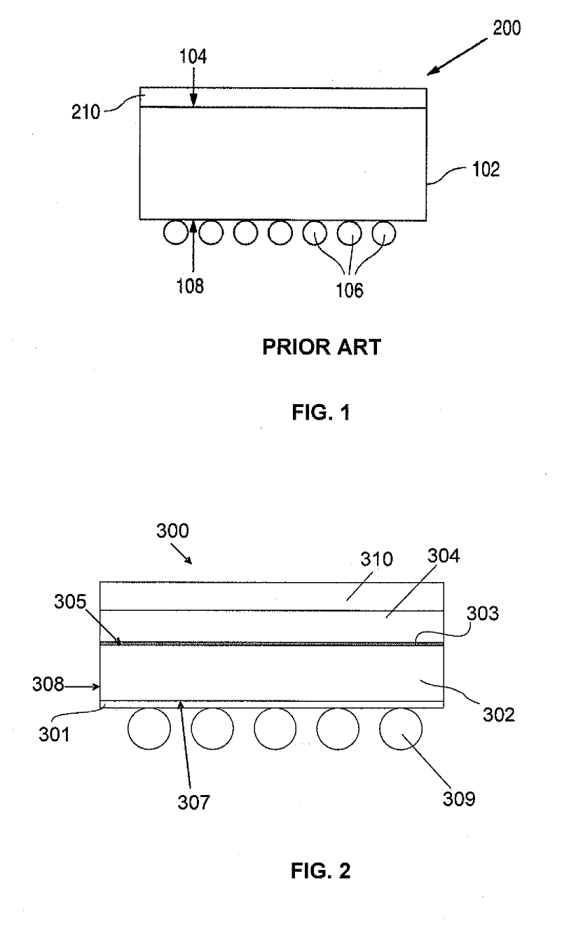

### DESCRIPTION OF THE PREFERRED EMBODIMENT

The present invention is described with preferred embodiments and accompanying drawings. It should be appreciated that all the embodiments are merely used for illustration. Although the present invention has been described in term of a preferred embodiment, the invention is not limited to this embodiment. It will be understood, however, to one skilled in the art, that the present invention may be practiced without some or all of these specific details. In other instances, well known process operations have not been described in detail in order to not unnecessarily obscure the present invention.

FIG. 2 illustrates a cross-section diagram of a structure of semiconductor device package 300 according to the present invention. The package 300 comprises at least one die 302 having a back surface 305 and an active surface 307. A redistribution layer (RDL) 301 is formed over the die 302; a plurality of contact pads or bumps 309 connected with the RDL 301 and therefore the bumps 309 formed upon the active surface 307 of the die 302 keeps electrical connection with the die 302. An adhesive layer 303 is formed on the back surface of the die 302. The conductive layer 304 is formed on the surface of the adhesive layer 303 opposite to the adhesive layer 303. The protection substrate 311 is formed on the conductive layer 304 opposite to the adhesive layer 303. In one embodiment, the top surface of the protection substrate 311 is employed as a laser or ink marking area.

In one embodiment, the material of the adhesive layer 303 includes elastic type material having an elastic property to absorb the external force and/or acting as the buffer layer. The material of the protection substrate 311 preferably includes BT, PI, FR5, FR4, or fiberglass and other commonly used soft substrates for semiconductor packaging.

The conductive layer 304 is a deposit layer containing Ti, Ni/Cr, Ni/V, Cu, or Ni.

In another embodiment, the conductive layer 304 is a printing conducted layer containing Ag, Ni, or Sn paste. In another embodiment, the conductive layer 304 means the adhesive layer 303 containing Ag, Ni, Au, Cu, or Pt. In another embodiment, the conductive layer 304 is a layer of metal or an elastic layer with metal in it. Because the conductive layer 304 contains metal, the conductive layer 304 works as the EMI shielding layer; the conductive layer 304 also works for absorbing the external force, since it is an elastic material.

The thickness of the protection substrate 311 is approximately 50-200 μm. Preferably, the thickness of the protection substrate 311 can be 50, 100 or 200 μm. In the other embodiment, the thickness of the protection substrate 311 is substantially as near as the thickness of the die 302. The coefficient of thermal expansion (CTE) of the protection substrate 311 is about 14-17, and is preferably matching with the CTE of the printed circuit board (PCB) during the process.

Besides utilizing the protection substrate 311 for covering and protecting the die 302, the force between the protection substrate 311 and the die 302 can be further absorbed and buffered by the adhesive layer 303 and the conductive layer 304 due to its elastic property. Especially, the external forces at the lateral sides 308 can be reduced in the thinner package structure, while the package size is between 50 to 200 μm, and preferably, the size is about 100-300 μm for the Wafer Level-Chip Scale Package (WL-CSP) process.

According to another aspect of the invention, the present invention further provides a method for forming a semiconductor device package.

First, a plurality of die 302 is provided on a wafer, and each die 302 has a back side surface 305 and an active surface 307. The adhesive layer 303 is formed on the back surface 305 of the die 302 and then the conductive layer 304 is formed on the adhesive layer 303. At last the protection substrate 311 is formed on the adhesive layer 303. In one embodiment the conductive layer 304 is formed by depositing, or by printing. In another embodiment, the conductive layer 304 means the adhesive layer 303 with metal in it, and the metal is introduced by doping.

In one embodiment, the protection substrate 311 is formed by performing a panel bonding (lamination) method.

A plurality of bumps 309 are formed on the active surface 307 of the die 302, and the bumps 309 are employed for electrical connection. After the aforementioned processes are finished, the finished package is diced into individual die by a commonly known singulation process.

The singulation process is described below: a scribe line (not shown) is disposed between each die 302, and the plurality of die 302 is separated into individual die for singulation along the scribe line. In one embodiment, a conventional sawing blade is used during the singulation process. The blade is aligned to the scribe line to separate the dice into individual die during the singulation process.

During the singulation process, the back side structure, particularly the conductive layer 304, acts as a protection scheme in the present invention. Because it is an elastic material, it release the external force exerted during the singulation, and therefore prevents the package from cracking or warping, thereby protecting the package structure to increase the packaging yield and quality.

According to the aspect of the present invention, the present invention provides a structure of semiconductor device having a back side protection scheme. The backside scheme includes an adhesive layer, a conductive layer and a substrate, wherein the adhesive layer is formed on the back surface of the die; the conductive layer is formed on the surface of the adhesive layer opposite to the adhesive layer and the protection substrate is formed on the conductive layer opposite to the adhesive layer. The conductive layer is an elastic and conductive layer.

The present invention also provides a method preventing a cracking or warping issue during the packaging process. An elastic and conductive layer is formed in the packaging process; the external force exerted during the process is released and the conductive layer also helps to make the substrate combine with the package more tightly. Therefore, the present invention discloses a method for enhancing the yield and lowering the manufacturing cost.

Therefore, the chip scale package structure disclosed by the present invention can provide effects unexpected in the prior art, and solve the problems of the prior art. The structure may apply to wafer or panel industry and also can be applied and modified to other related applications.

As will be understood by a person skilled in the art, the foregoing preferred embodiments of the present invention are illustrative of the present invention, rather than limiting the present invention. Having described the invention in connection with a preferred embodiment, modification will suggest itself to those skilled in the art. Thus, the invention is not to be limited by this embodiment. Rather, the invention is intended to cover various modifications and similar arrangements included within the spirit and scope of the appended claims, the scope of which should be accorded the broadest interpretation so as to encompass all such modifications and similar structures.

Having described the invention, the following is claimed:

1. A structure of semiconductor device package, comprising:
a die having a back surface and an active surface formed thereon;
a conductive layer formed upon said back surface of said die, wherein said conductive layer is elastic and contains conductive material;
a protection substrate formed on said conductive layer; and
a plurality of bumps formed on said active surface of said die.

2. The structure in claim 1, wherein said conductive layer is doped with a conductive particle.

3. The structure in claim 2, wherein said conductive particle is Ag, Ni, Au, Cu, or Pt.

4. The structure in claim 1, wherein the structure further contains an adhesive layer between said protection layer and said conductive layer.

5. The structure in claim 1, wherein the material of said adhesive layer is an elastic type material.

6. The structure in claim 4, wherein said conductive layer contains Ti, Ni/Cr, Ni/V, Cu, or Ni.

7. The structure in claim 4, wherein said conductive layer contains Ag, Ni, or Sn.

8. The structure in claim 1, wherein the material of said protection substrate is a soft substrate.

9. The structure in claim 8, wherein the material of said protection substrate includes BT, PI, FR5, FR4 or fiberglass.

10. The structure in claim 1, wherein the thickness of said protection substrate is approximately 50-200 μm.

11. The structure in claim 1, wherein the structure further comprises laser or ink marks formed on the top surface of said protection substrate.

12. A method for forming a semiconductor device package, comprising:
providing a plurality of die having a back surface and an active surface on a wafer;
forming a conductive layer upon said back surface of said die;
forming protection substrates on said adhesive layer;
forming a plurality of bumps on said active surface of each die; and
dicing said plurality of die into individual die for singulation, wherein said dicing is exerting external force on said protection substrate.

13. The method in claim 12, wherein said step of forming the conductive layer is by printing.

14. The method in claim 12, wherein said step of forming the conductive layer is by depositing.

15. The method in claim 12, wherein said step of forming the conductive layer is conducted by forming an adhesive layer with a conductive particle.

16. The method in claim 12, wherein the method further includes forming an adhesive layer between said back surface of said die and said conductive layer.

17. The method in claim 12, wherein said step of dicing said plurality of die is performed by a sawing blade.
